(19) United States
(12) Patent Application Publication
(10) Pub. No.: US 2005/0185788 A1
(43) Pub. Date: Aug. 25, 2005

(54) Keypad adapted for use in dual orientations

(76) Inventor: Sean P. Daw, Chicago, IL (US)

Correspondence Address: Lawrence J. Chapa;Motorola, Inc., 1303 East Algonquin Road, Schaumburg, IL, 60196, US

(21) Appl. No.: 11/065,109

(22) Filed: Feb. 23, 2005

Related U.S. Application Data
(63) Continuation-in-part of application No. 29/200,032, filed on Feb. 23, 2004.

(51) Int. Cl. H03M 11/00; H03K 17/94

(52) U.S. Cl. 379/369; 379/370

(57) ABSTRACT

A keypad is provided, which comprises a plurality of user actuated keys, wherein the keys are generally arranged in a grid having a plurality of rows and a plurality of columns. Placement of the keys in one or more of the rows increasingly flares outward at one end of the grid, relative to the other rows.

### CROSS REFERENCE TO RELATED APPLICATIONS

This application is a continuation-in-part of U.S. Patent Application Serial No. 29/200,032, filed Feb. 23, 2004.

### FIELD OF THE INVENTION

The present invention relates generally to the arrangement of keys in a keypad. More particularly, the present invention relates to the arrangement of keys for use in a dual-orientation keypad.

### BACKGROUND OF THE INVENTION

There has been a convergence of functionality in hand-held devices, where some of the features and functions of previously separate devices have been combined into a single common device. Examples of convergence includes the inclusion of one or more of radio telephone, digital camera, personal digital assistant, digital audio player and/or two-way pager (i.e. text messaging) type features in the same device. With the convergence of previously separate features comes the challenge of providing a suitable interface, which accommodates all of the different feature sets that have been incorporated within the same device.

Cellular telephone interfaces have traditionally been focused on numeric keypads and the input of telephone numbers for the placement of telephone calls, the incorporation of text messaging type features has made the entry of alphabetic text more desirable.

In some instances, various techniques, have been developed to input alphabetic text using the numeric keypad. In some instances, these methods have used the association of multiple alphabetic characters with each of the numeric keys. However where multiple alphabetic characters have been associated with a common key, in order to identify a particular one of the multiple alphabetic characters which is intended, several different techniques have been developed. One such technique has included using repeated sequential taps of the same numeric key to cycle through each of the associated alphabetic characters, until the desired character has been properly selected. Such a technique has sometimes been referred to as multi-tap.

In some other instances, keypads have been developed, which enable a key to be actuated in different ways to distinguish between different potential character entries associated with a particular key. In some of these instances, a single key cap can be associated with multiple switches, which depending upon how the key cap is depressed will actuate different combinations of the associated switches. Each combination can be uniquely associated with a different desired character entry.

However in each instance, while the above noted approaches provide a technique for the entry of alphabetic characters, which is adapted for use with a number of keys corresponding to a more traditional numeric keypad, the approaches for text entry diverge from the more traditional “QWERTY”-style keypads, which many users have become accustomed. Such differences can sometimes discourage use of the particular functions for which the forms of user interface have been compromised, and as a result limit the effectiveness of attempts to incorporate the different feature sets in the same device.

Still further, the incorporation of additional keys in support of a more traditional “QWERTY”-style keypad, can make one handed numeric text entry, which is commonly associated with cellular radiotelephone type operation, more confusing or difficult. Still further a “QWERTY”-style keypad having a more pronounced width, which accommodates the more traditional placement of the keys relative to the display, can make the dimensioning of the overall device, which is also intended to support the one handed operation in radiotelephone mode, a bit of a challenge. Consequently a keypad arrangement, which more readily conveniently accommodates multiple modes of operation, such as text entry and radio telephone operation, would be beneficial.

### SUMMARY OF THE INVENTION

The present invention provides for a keypad, which comprises a plurality of user actuated keys, wherein the keys are generally arranged in a grid having a plurality of rows and a plurality of columns. Placement of the keys in one or more of the rows increasingly flares outward at one end of the grid, relative to the other rows.

In at least one embodiment, the placement of the keys in one or more of the columns is generally arranged in an arc having a curvature. In at least some of these instances the keys in at least one of the ends of the grid in one or more of the columns, which are arranged in an arc having a curvature, curves toward a side of the keypad wherein a portion of a user that actuates the keys is intended to originate.

In at least a further embodiment, the keypad is incorporated as part of a hand held device, where in some instances the hand held device has a two part housing including an upper housing and a lower housing, which rotate relative to one another, and the keypad is incorporated as part of the lower housing.

In some of these instances, the hand held device further includes a bidirectional hinge coupled to each of the upper housing and the lower housing, where the bidirectional hinge is adapted for selectively rotating the upper housing and lower housing, relative to one another, about each of at least a pair of axes. In some instances, a first one of the at least a pair of axes is adapted for rotating the upper housing and lower housing for use in a portrait mode. In some instances, a second one of the at least a pair of axes is adapted for rotating the upper housing and lower housing for use in a landscape mode.

These and other features, and advantages of this invention are evident from the following description of one or more preferred embodiments of this invention, with reference to the accompanying drawings.

### BRIEF DESCRIPTION OF THE FIGURES

The present invention will be described by way of exemplary embodiments, but not limitations, illustrated in the accompanying drawings in which like references denote similar elements, and in which:

FIG. 1 is a front view of a keypad, in accordance with at least one embodiment of the present invention;

FIG. 2 is a front view of a hand held device having a two part housing rotated relative to one another in a portrait mode open position, which incorporates at least one embodiment of the keypad illustrated in FIG. 1;

FIG. 3 is a front view of a hand held device having a two part housing rotated relative to one another in a landscape mode open position, which incorporates at least one embodiment of the keypad illustrated in FIG. 1; and

FIGS. 4A-4C are partial front views of a hand held device, being held by a user's hand, having a two part housing rotated relative to one another in a portrait mode open position, which highlights the position of the thumb relative to the keypad as the user attempts to access different areas of a keypad forming a part of the lower housing.

### DETAILED DESCRIPTION

As required, detailed embodiments of the present invention are disclosed herein, however, it is to be understood that the disclosed embodiments are merely exemplary of the invention, which can be embodied in various forms. Therefore, specific structural and functional details disclosed herein are not to be interpreted as limiting, but merely serve as a basis for the claims and as a representative basis for teaching one skilled in the art to variously employ the present invention in virtually any appropriately detailed structure. Further, the terms and phrases used herein are not intended to be limiting, but rather, to provide an understandable description of the invention.

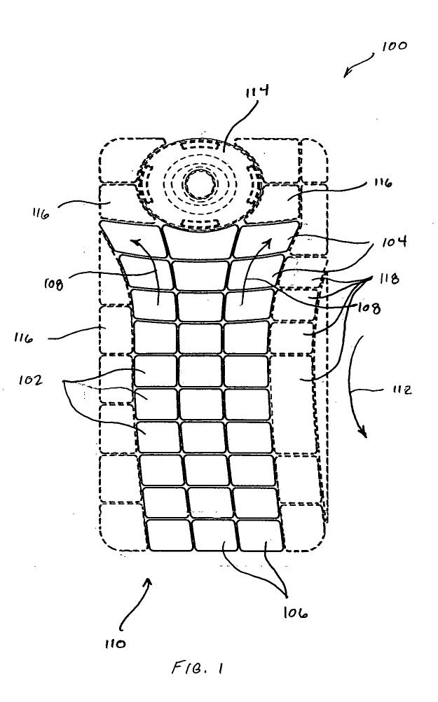

FIG. 1 illustrates a front view of a keypad 100, in accordance with at least one embodiment of the present invention. The keypad includes a plurality of user actuated keys 102 arranged in a grid having a plurality of rows 104 and a plurality of columns 106, where the placement of the keys 102 in one or more rows 104 at one end of the grid increasingly flare outward 108, relative to the other rows. In at least the illustrated embodiment, the user actuated keys are arranged in a substantially common plane, where in the case of the illustrated embodiment, the common plane is generally substantially parallel to plane of the drawing sheet.

The flaring outward 108 of the keys within one or more rows, in at least some embodiments, includes the placement of the keys within the corresponding row across a wider area. In at least some instances, as the keys are placed across a wider area, the width of at least some of the keys correspondingly increase.

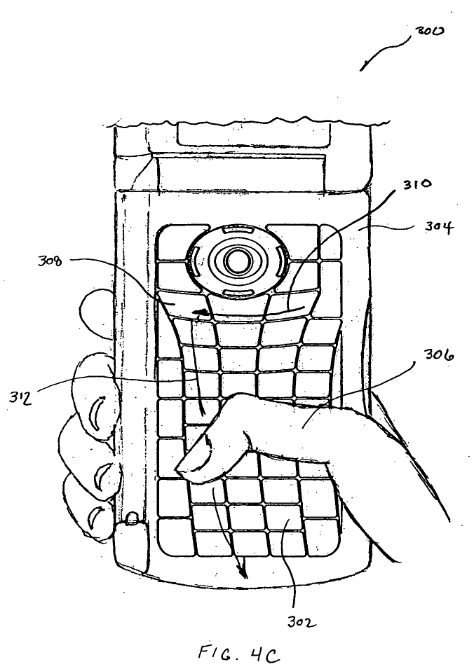

In accordance with at least some embodiments, the placement of the keys in one or more of the columns is generally arranged in an arc having a curvature. In the illustrated embodiment, the placement of the keys at at least one end 110 of the grid curves 112 towards the side of the keypad where the portion of the user, such as a thumb, that actuates the keys is intended to originate (see FIGS. 4A-4C).

In at least some instances the user actuated keys are intended for character input, which can include numbers, letters and/or symbols. Optionally, one or more additional keys can be included, which correspond to the navigation control 114, i.e. the control of a cursor on a display, or the selection of text, for example, identified by the same being highlighted. Further keys 116 can be associated with executing a particular function, such as answering an incoming call, placing an outgoing call, or taking a picture. Still frtiher keys 118, may provide additional character input.

In at least some embodiments, the keypad will be incorporated as part of a hand held device. Examples of handheld devices includes radio telephones, such as a cellular telephone; a text messaging device, such as a pager; a remote control; a digital music player; a personal digital assistant; a pocket personal computer; a global positioning hand terminal; a digital camera; a portable game player; a portable movie player; and the like, and/or various multi-mode devices including various combinations of features from the same.

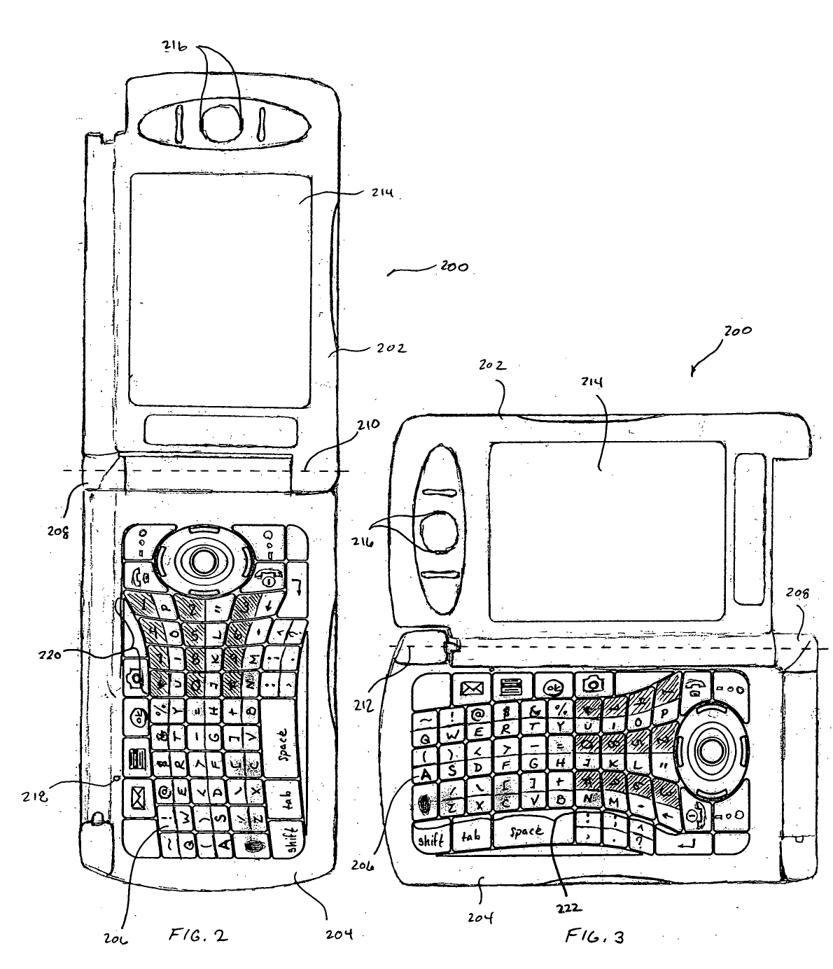

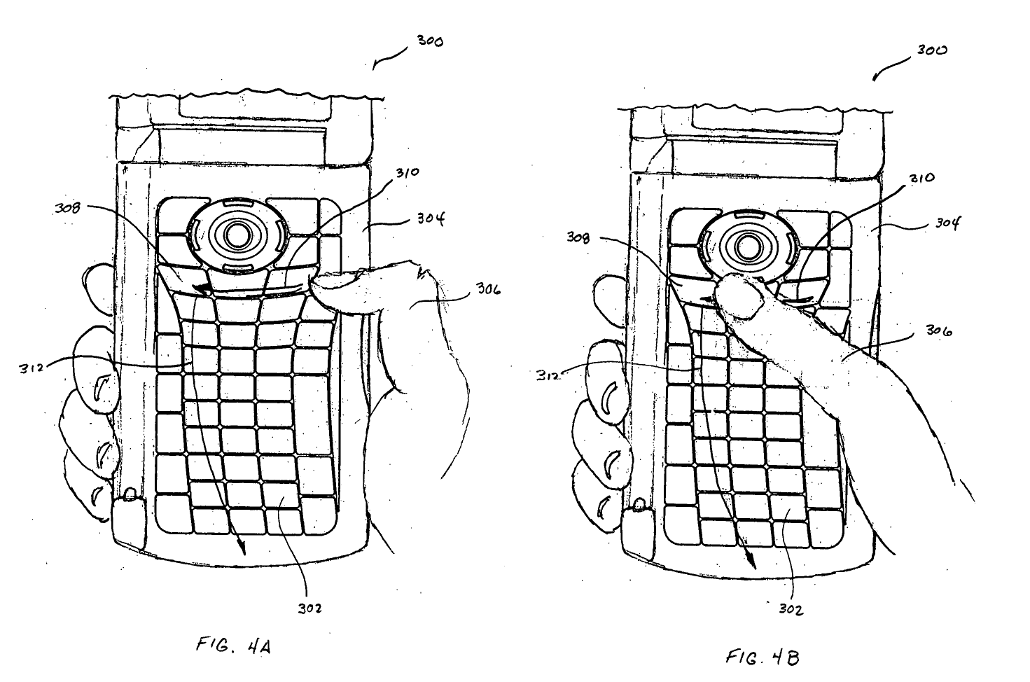

FIGS. 2 and 3 illustrate a front view of an example of one such device 200, namely a cellular telephone, which exemplary incorporates a variety of features including the ability to play music, take pictures, send and receive text messages, as well as make cellular telephone calls. The hand held device has a two part housing, where the housing parts rotated relative to one another. The two part housing includes an upper housing 202 and a lower housing 204. In the illustrated example, a keypad 206, consistent with the keypad 100, illustrated in FIG. 1, is incorporated as part of the lower housing 204. The device 200 additionally includes a bidirectional hinge 208, which is coupled to each of the upper housing 202 and the lower housing 204, which is adapted for selectively rotating the upper housing and the lower housing, relative to one another, separately, about each of at least a pair of axes 210, 212. In the illustrated embodiment, the upper housing 202 includes a display 214 for use in producing a visual output, and speaker ports 216 for use in producing an audio output.

In FIG. 2, the upper housing 202 and the lower housing 204 are rotated about axis 210 toward an open position in portrait mode. In FIG. 3, the upper housing 202 and the lower housing 204 are rotated about axis 212 toward an open position in landscape mode.

In portrait mode, the two part housing of the hand held device 200 is arranged in a position, which has traditionally supported the operation of a radio telephone, where the speaker ports 216 and a microphone port 218 are appropriately spaced so as to correspond to the distance between the user's mouth and at least one of the user's ears. Correspondingly, at least a portion 220 of the keys in the keypad 206 are substantially arranged as a telephone numeric keypad to support telephone number entry. In some instances, the portion 220 of the keys in the keypad 206 represent a subset of the plurality of user actuated keys forming the keypad.

In landscape mode, the two part housing of the hand held device 200 is arranged in a position, which has traditionally supported the operation of a two-way pager, where the display 214 is positioned above the keypad 206 that is used for text entry. Such an arrangement further supports a physically wider keypad, which is consistent with a “QWERTY” style keypad. Correspondingly, in the landscape mode orientation, at least a portion of the plurality of keys are substantially arranged as a “QWERTY” style keypad 222.

In the illustrated embodiment, at least some of the plurality of keys, which are used for the numeric keypad are additionally used as part of the “QWERTY” style keypad 222. In some instances, a switch may be used to detect, which one of the two axes along which the two housing parts have rotated for establishing the current function of any keys, which are common between the telephonic numeric keypad and the “QWERTY” style keypad 222.

While the “QWERTY” style keypad 222 and telephonic numeric keypad have been specifically referenced, one skilled in the art will readily appreciate that other types of keypad layouts are similarly possible without departing from the teachings of the present invention, including differing character assignments for each of the respective keys.

In the illustrated embodiment, as noted above, the portion of the plurality of keys forming the telephonic numeric keypad 220 is a subset of the plurality of user actuated keys forming the keypad 206. Additionally, the portion of the plurality of keys forming the telephonic numeric keypad 220 is a subset of the plurality of keys forming the “QWERTY” style keypad 222. In order to assist in identifying the keys associated with the telephonic numeric keypad 220, from the plurality of keys, which are not part of the subset of keys forming the telephonic numeric keypad 220, the keys associated with the telephonic numeric keypad 220 can be visually distinct. In the illustrated embodiment, visual distinctiveness includes being a different color, noted by the shading of the subset of keys forming the telephonic numeric keypad 220, as well as the placement and positioning of the keys. In the illustrated embodiment, the subset of keys forming the telephonic numeric keypad 220 are substantially represented at the end of the grid where the rows 104 increasingly flare outward 108.

In accordance with at least some embodiments of the present invention, the specific placement of the plurality of keys within the grid can further facilitate one handed operation, while performing character entry in a portrait mode open position. FIGS. 4A-4C are partial front views of a hand held device 300, being held by a user's hand, having a two part housing rotated relative to one another in a portrait mode open position, which highlights the position of the user's thumb 306 relative to the keypad as the user attempts to access different areas of a keypad 302 forming a part of the lower housing 304.

More specifically, FIG. 4A illustrates a user accessing with their right thumb the upper right portion of the grid of keys corresponding to the end 308 of the grid where the keys in one or more of the rows increasingly flare outward, relative to the other rows. A first arrow 310 illustrates an example of the path that the thumb 306 may travel in accessing the upper left portion of the grid of keys. FIG. 4B illustrates a user accessing with their thumb 306 the upper left portion of the grid of keys.

A second arrow 312 illustrates an example of the path that the thumb 306 may travel in accessing the lower left portion of the grid of keys, traveling from the upper left portion of the grid of keys. As the thumb 306 travels downward, the natural path traverses an arc having a curvature that curves toward the side of the keypad 302, where the thumb originates. This curvature at least partially coincides with the curvature of the lower end of one or more of the columns of keys forming at least part of the grid of keys, which in turn increasingly facilitates one handed text entry.

While the illustrated embodiment, shows a curvature consistent with right handed operation, one skilled in the art will readily appreciate, that the curvature could be reversed to facilitate left handed operation. In such an instance, it may similarly be beneficial to reverse the side of the lower housing 304 where the dual axis hinge and the axis of rotation is located for facilitating the rotation of the two part housing for rotation in landscape mode.

As described and illustrated, the present keypad provides an ergonomic and cognitively correct layout for both portrait and landscape uses, which offer users a familiar format, which eases the users into bi-directional use scenarios.

While the preferred and other embodiments of the invention have been illustrated and described, it will be clear that the invention is not so limited. Numerous modifications, changes, variations, substitutions, and equivalents will occur to those of ordinary skill in the art without departing from the spirit and scope of the present invention as defined by the following claims.

1. A keypad comprising a plurality of user actuated keys, wherein the keys are generally arranged in a grid having a plurality of rows and a plurality of columns, and placement of the keys in one or more of the rows increasingly flares outward at one end of the grid, relative to the other rows.

2. A keypad in accordance with claim 1, wherein the width of the keys correspondingly increases as the placement of the keys proximate the one end of the grid flares outward.

3. A keypad in accordance with claim 1, wherein the plurality of user actuated keys are for character input.

4. A keypad in accordance with claim 3, wherein character input includes one or more of numbers, letters and symbols.

5. A keypad in accordance with claim 1, further comprising a navigation key, wherein the navigation key is proximate the one end of the grid, where the keys in the one or more rows flare outward.

6. A keypad in accordance with claim 1, wherein the placement of the keys in one or more of the columns is generally arranged in an arc having a curvature.

7. A keypad in accordance with claim 6, wherein the keys in at least one of the ends of the grid in one or more of the columns, which are arranged in an arc having a curvature, curves toward a side of the keypad wherein a portion of a user that actuates the keys is intended to originate.

8. A keypad in accordance with claim 1, wherein the keys are arranged in a substantially common plane.

9. A keypad in accordance with claim 1, wherein the keypad is incorporated as part of a hand held device.

10. A keypad in accordance with claim 9, wherein the hand held device is a radio telephone.

11. A keypad in accordance with claim 9, wherein the hand held device has a two part housing including an upper housing and a lower housing, which rotate relative to one another, and the keypad is incorporated as part of the lower housing.

12. A keypad in accordance with claim 11, wherein the hand held device further includes a bidirectional hinge coupled to each of the upper housing and the lower housing, and wherein the bidirectional hinge is adapted for selectively rotating the upper housing and the lower housing, relative to one another, about each of at least a pair of axes.

13. A keypad in accordance with claim 12, wherein a first one of the at least a pair of axes is adapted for rotating the upper housing and lower housing for use in a portrait mode.

14. A keypad in accordance with claim 13, wherein when the upper housing and lower housing are rotated for use in the portrait mode at least a portion of the plurality of keys are substantially arranged as a telephonic numeric keypad.

15. A keypad in accordance with claim 14, wherein the portion of the plurality of keys substantially arranged as the telephonic numeric keypad is a subset of the plurality of user actuated keys.

16. A keypad in accordance with claim 15, wherein the portion of the plurality of keys arranged as the telephonic numeric keypad are visually distinct from the plurality of keys, which are not part of the subset of keys forming the telephonic numeric keypad.

17. A keypad in accordance with claim 16, wherein being visually distinct includes being a different color.

18. A keypad in accordance with claim 12, wherein a second one of the at least a pair of axes is adapted for rotating the upper housing and lower housing for use in a landscape mode.

19. A keypad in accordance with claim 18, wherein when the upper housing and lower housing are rotated for use in the landscape mode at least a portion of the plurality of keys are substantially arranged as a QWERTY keypad.
